(19) United States
(12) Patent Application Publication
(10) Pub. No.: US 2009/0321123 A1
(43) Pub. Date: Dec. 31, 2009

(54) METHOD FOR PRODUCING STRUCTURED ELECTRICALLY CONDUCTIVE SURFACES

(75) Inventors: Rene Lochtman, Mannheim (DE); Jürgen Kaczun, Wachenheim (DE); Norbert Schneider, Ajtrip (DE); Jürgen Pfister, Speyer (DE); Norbert Wagner, Mutterstadt (DE); Dieter Hentschel, Boblinger (DE)

Correspondence Address: CONNOLLY BOVE LODGE & HUTZ, LLP, P O BOX 2207, WILMINGTON, DE, 19899, US

(73) Assignee: BASF SE Patents, Trademarks and Lincenses, Ludwigshafen (DE)

(21) Appl. No.: 12/375,702

(22) PCT Filed: Jul. 31, 2007
(86) PCT No.: PCT/EP07/57858

§ 371 Date: Jan. 30, 2009

(30) Foreign Application Priority Data
Aug. 3, 2006 (EP) 06118411.5

(51) Int. Cl. H05K 1/11; C25D 5/02; H01B 13/00; B05D 5/12

(52) U.S. Cl. 174/261; 427/97.3; 205/125; 216/13; 427/534; 427/75

(57) ABSTRACT

The invention relates to a method for producing structured, electrically-conductive surfaces (3, 11) on an electrically nonconductive support (1), in which the structured and/or full-area electrically-conductive surfaces (3) of a first plane are applied onto the support (1) in a first step, an insulating layer (9) is applied in a second step at the positions where structured and/or full-area electrically-conductive surfaces (11) of a second plane cross the structured and/or full-area electrically-conductive surfaces (3) of the first plane and no electrical contact is intended to take place between the structured and/or full-area electrically-conductive surfaces of the first plane (3) and of the second plane (11), in a third step the structured and/or full-area electrically-conductive surfaces (11) of the second plane are applied according to the first step, and the second and third steps are optionally repeated.

The invention relates to a method for producing structured electrically-conductive surfaces on an electrically nonconductive support.

The method according to the invention is suitable, for example, for producing conductor tracks on printed circuit boards, RFID antennas, transponder antennas or other antenna structures, chip card modules, flat cables, seat heaters, foil conductors, conductor tracks in solar cells or in LCD/plasma screens or electrolytically coated products in any form. The method is also suitable for producing decorative or functional surfaces on products, which may be used for example for shielding electromagnetic radiation, for thermal conduction or as packaging.

In order to be able to produce complex circuits, it is often necessary to produce a plurality of conductor tracks above one another with an insulation layer lying between them. In this case, on the one hand, it is possible to provide a plurality of printed circuit boards on which conductor tracks are respectively configured, and to stack these on one another, in which case two printed circuit boards are respectively separated from one another by an additional full-area insulating layer. In order to be able to connect the individual conductor tracks to one another, vias are provided in the printed circuit boards, through which the conductor tracks can be contacted with one another. As an alternative, it is known for example from Hans-Joachim Hanke, Baugruppentechnologie der Elektronik, Hybridträger [module technology in electronics, hybrid supports], pages 41 to 45, Verlag Technik Berlin, 1994, to provide a plurality of planes of conductor tracks on a printed circuit board, which are respectively separated from one another at the crossing points by an insulating layer. With currently known methods, at most four conductor planes are possible in this way, with the insulating layer respectively being provided only in the region where there is an underlying conductor track.

Such conductor tracks are generally produced, for example, by first applying a structured bonding layer onto the support body. A metal foil or a metal powder is fixed on this structured bonding layer. As an alternative, it is also known for a metal foil or a metal layer surface-wide to be applied on a support body made of a plastic material, pressed against the support body with the aid of a structured heated die, and fixed by subsequently curing it. The metal layer is structured by mechanically removing the regions of the metal foil, or the metal powder, which are not connected to the bonding layer or to the support body. Such a method is described, for example, in DE-A 101 45 749. A disadvantage of this method is that a large amount of material must be removed again after applying each conductor layer. Furthermore, with this method it is not possible to apply an insulating layer.

Further disadvantages of the methods known from the prior art are the poor bonding and the lack of homogeneity and continuity of the metal layer deposited by electroless and/or electrolytic metallization. This is mostly attributable to the fact that the electrically-conductive particles are embedded in a matrix material and are therefore only to a small extent exposed on the surface, so that only a small proportion of these particles is available for electroless or electrolytic metallization. This is problematic above all when using very small particles (particles in the micro- to nanometer range). A homogeneous, continuous metal coating can therefore be produced only with great difficulty or not at all, so that there is no process reliability. This effect is exacerbated even further by an oxide layer present on the electrically-conductive particles.

Another disadvantage of the previously known methods is the slow electroless or electrolytic metallization. When the electrically-conductive particles are embedded in the matrix material, the number of particles exposed on the surface, which are available as growth nuclei for the electroless or electrolytic metallization, is small. Inter alia, this is because during the application of printing dispersions, for example, the heavy metal particles sink into the matrix material and only few metal particles therefore remain on the surface.

Another disadvantage of the previously known methods especially for the production of printed circuit boards, for example multilayer printed circuit boards, is the elaborate multilayer structure. This is because owing to the limited space (only a certain number of conductor tracks and interconnections can be produced on a defined area) and owing to the printed circuit board designs, more and more inner layers, sometimes 18 or more of them, and two outer layers must be connected to one another, for example by lamination. To this end, in the general case, an insulation layer must respectively also be applied between two inner layers or between an inner layer and an outer layer. For the purpose of contacting, for example to conductor tracks on two different inner layers, in the general case these must also still be connected to one another elaborately. To this end, for example when producing so-called buried vias, these inner layers must be elaborately bored and metallized. There are also connections between the outer layers and an underlying inner layer, so-called microvias i.e. small blind holes. These are elaborately bored mechanically or by means of laser beams, or introduced photochemically or by a plasma etching process.

Another disadvantage of the methods described in the prior art is the large overall thickness of the printed circuit boards fabricated in this way.

It is an object of the present invention to provide a method with which electrically-conductive surfaces in a plurality of planes can be applied simply and inexpensively on an electrically nonconductive support, and which allows a high conductor track density as well as the production of flat printed circuit boards.

The object is achieved by a method for producing structured and/or full-area electrically-conductive surfaces on an electrically nonconductive support, which comprises the following steps:
a) applying the structured and/or full-area electrically-conductive surfaces of a first plane onto the electrically nonconductive support,
b) applying an insulating layer at the positions where structured and/or full-area electrically-conductive surfaces of a second plane cross the structured and/or full-area electrically-conductive surfaces of the first plane and no electrical contact is intended to take place between the structured and/or full-area electrically-conductive surfaces of the first plane and of the second plane,
c) applying the structured and/or full-area electrically-conductive surfaces of the second plane according to step a),
d) optionally repeating steps b) and c).

Rigid or flexible supports, for example, are suitable as supports onto which the electrically-conductive, structured or full-area surface can be applied. The support is preferably electrically nonconductive. This means that the resistivity is more than 10⁹ ohm×cm. Suitable supports are for example reinforced or unreinforced polymers, such as those conventionally used for printed circuit boards. Suitable polymers are epoxy resins or modified epoxy resins, for example bifunctional or polyfunctional Bisphenol A or Bisphenol F resins, epoxy-novolak resins, brominated epoxy resins, aramid-reinforced or glass fiber-reinforced or paper-reinforced epoxy resins (for example FR4), glass fiber-reinforced plastics, liquid-crystal polymers (LCP), polyphenylene sulfides (PPS), polyoxymethylenes (POM), polyaryl ether ketones (PAEK), polyether ether ketones (PEEK), polyamides (PA), polycarbonates (PC), polybutylene terephthalates (PBT), polyethylene terephthalates (PET), polyimides (PI), polyimide resins, cyanate esters, bismaleimide-triazine resins, nylon, vinyl ester resins, polyesters, polyester resins, polyamides, polyanilines, phenol resins, polypyrroles, polyethylene naphthalate (PEN), polymethyl methacrylate, polyethylene dioxithiophene, phenolic resin-coated aramid paper, polytetrafluoroethylene (PTFE), melamine resins, silicone resins, fluorine resins, allylated polyphenylene ethers (APPE), polyether imides (PEI), polyphenylene oxides (PPO), polypropylenes (PP), polyethylenes (PE), polysulfones (PSU), polyether sulfones (PES), polyaryl amides (PAA), polyvinyl chlorides (PVC), polystyrenes (PS), acrylonitrile-butadiene-styrene (ABS), acrylonitrile-styrene acrylate (ASA), styrene acrylonitrile (SAN) and mixtures (blends) of two or more of the aforementioned polymers, which may be present in a wide variety of forms. The substrates may comprise additives known to the person skilled in the art, for example flame retardants.

In principle, all polymers mentioned below in respect of the matrix material may also be used. Other substrates likewise conventional in the printed circuit industry are also suitable.

Composite materials, foam-like polymers, Styropor®, Styrodur®, polyurethanes (PU), ceramic surfaces, textiles, pulp, board, paper, polymer-coated paper, wood, mineral materials, silicon, glass, vegetable tissue and animal tissue are furthermore suitable substrates.

The substrate may be either rigid or flexible.

The structured and/or full-area electrically-conductive surface of the first plane is, for example, applied by a base layer first being applied with a dispersion, which contains electrically-conductive particles in a matrix material, and at least partially cured and/or dried, then the particles being at least partially exposed and subsequently provided with a metal layer by electroless and/or electrolytic coating.

In a first step, the structured or full-area base layer is applied onto the support by using a dispersion, which contains electrically-conductive particles in a matrix material. The electrically-conductive particles may be particles of arbitrary geometry made of any electrically-conductive material, mixtures of different electrically-conductive materials or else mixtures of electrically-conductive and nonconductive materials. Suitable electrically-conductive materials are, for example, carbon, electrically-conductive metal complexes, conductive organic compounds or conductive polymers or metals, for example zinc, nickel, copper, tin, cobalt, manganese, iron, magnesium, lead, chromium, bismuth, silver, gold, aluminum, titanium, palladium, platinum, tantalum and alloys thereof or metal mixtures which contain at least one of these metals. Suitable alloys are for example CuZn, CuSn, CuNi, SnPb, SnBi, SnCo, NiPb, ZnFe, ZnNi, ZnCo and ZnMn. Aluminum, iron, copper, nickel, zinc, carbon and mixtures thereof are particularly preferred.

The electrically-conductive particles preferably have an average particle diameter of from 0.001 to 100 μm, preferably from 0.005 to 50 μm and particularly preferably from 0.01 to 10 μm. The average particle diameter may be determined by means of laser diffraction measurement, for example using a Microtrac X100 device. The distribution of the particle diameters depends on their production method. The diameter distribution typically comprises only one maximum, although a plurality of maxima are also possible.

The surface of the electrically-conductive particle may be provided at least partially with a coating. Suitable coatings may be inorganic (for example SiO₂, phosphates) or organic in nature. The electrically-conductive particle may of course also be coated with a metal or metal oxide. The metal may likewise be present in a partially oxidized form.

If two or more different metals are intended to form the electrically-conductive particles, then this may be done using a mixture of these metals. It is particularly preferable for the metal to be selected from the group consisting of aluminum, iron, copper, nickel, zinc and tin.

The electrically-conductive particles may nevertheless also contain a first metal and a second metal, in which the second metal is present in the form of an alloy (with the first metal or one or more other metals), or the electrically-conductive particles may contain two different alloys.

Besides the choice of electrically-conductive particles, the shape of the electrical conductive particles also has an effect on the properties of the dispersion after coating. In respect of the shape, numerous variants known to the person skilled in the art are possible. The shape of the electrically-conductive particles may, for example, be needle-shaped, cylindrical, plate-shaped or spherical. These particle shapes represent idealized shapes and the actual shape may differ more or less strongly therefrom, for example owing to production. For example, teardrop-shaped particles are a real deviation from the idealized spherical shape in the scope of the present invention.

Electrically-conductive particles with various particle shapes are commercially available.

When mixtures of electrically-conductive particles are used, the individual mixing partners may also have different particle shapes and/or particle sizes. It is also possible to use mixtures of only one type of electrically-conductive particles with different particle sizes and/or particle shapes. In the case of different particle shapes and/or particle sizes, the metals aluminum, iron, copper, nickel, zinc and tin as well as carbon are likewise preferred.

As already mentioned above, the electrically-conductive particles may be added to the dispersion in the form of their powder. Such powders, for example metal powder, are commercially available goods or can be readily produced by means of known methods, for instance by electrolytic deposition or chemical reduction from solutions of metal salts or by reduction of an oxidic powder, for example by means of hydrogen, by spraying or atomizing a metal melt, particularly into coolants, for example gases or water. Gas and water atomization and the reduction of metal oxides are preferred. Metal powders with the preferred particle size may also be produced by grinding coarser metal powder. A ball mill, for example, is suitable for this.

Besides gas and water atomization, the carbonyl-iron powder process for producing carbonyl-iron powder is preferred in the case of iron. This is done by thermal decomposition of iron pentacarbonyl. This is described, for example, in Ullman's Encyclopedia of Industrial Chemistry, 5th Edition, Vol. A14, p. 599. The decomposition of iron pentacarbonyl may, for example, take place at elevated temperatures and elevated pressures in a heatable decomposer that comprises a tube of a refractory material such as quartz glass or V2A steel in a preferably vertical position, which is enclosed by a heating instrument, for example consisting of heating baths, heating wires or a heating jacket through which a heating medium flows.

Platelet-shaped electrically-conductive particles can be controlled by optimized conditions in the production process or obtained afterwards by mechanical treatment, for example by treatment in an agitator ball mill.

Expressed in terms of the total weight of the dried coating, the proportion of electrically-conductive particles preferably lies in the range of from 20 to 98 wt. %. A preferred range for the proportion of the electrically-conductive particles is from 30 to 95 wt. % expressed in terms of the total weight of the dried coating.

For example, binders with a pigment-affine anchor group, natural and synthetic polymers and derivatives thereof, natural resins as well as synthetic resins and derivatives thereof, natural rubber, synthetic rubber, proteins, cellulose derivatives, drying and non-drying oils etc. are suitable as a matrix material. They may—but need not—be chemically or physically curing, for example air-curing, radiation-curing or temperature-curing.

The matrix material is preferably a polymer or polymer blend.

Polymers preferred as a matrix material are, for example, ABS (acrylonitrile-butadiene-styrene); ASA (acrylonitrile-styrene acrylate); acrylic acrylates; alkyd resins; alkyl vinyl acetates; alkyl vinyl acetate copolymers, in particular methylene vinyl acetate, ethylene vinyl acetate, butylene vinyl acetate; alkylene vinyl chloride copolymers; amino resins; aldehyde and ketone resins; celluloses and cellulose derivatives, in particular hydroxyalkyl celluloses, cellulose esters such as acetates, propionates, butyrates, carboxyalkyl celluloses, cellulose nitrate; epoxy acrylate; epoxy resins; modified epoxy resins, for example bifunctional or polyfunctional Bisphenol A or Bisphenol F resins, epoxy-novolak resins, brominated epoxy resins, cycloaliphatic epoxy resins; aliphatic epoxy resins, glycidyl ethers, vinyl ethers, ethylene-acrylic acid copolymers; hydrocarbon resins; MABS (transparent ABS also containing acrylate units); melamine resins, maleic acid anhydride copolymers; methacrylates; natural rubber; synthetic rubber; chlorine rubber; natural resins; colophonium resins; shellac; phenolic resins; polyesters; polyester resins such as phenyl ester resins; polysulfones; polyether sulfones; polyamides; polyimides; polyanilines; polypyrroles; polybutylene terephthalate (PBT); polycarbonate (for example Makrolon® from Bayer AG); polyester acrylates; polyether acrylates; polyethylene; polyethylene thiophene; polyethylene naphthalates; polyethylene terephthalate (PET); polyethylene terephthalate glycol (PETG); polypropylene; polymethyl methacrylate (PMMA); polyphenylene oxide (PPO); polystyrenes (PS), polytetrafluoroethylene (PTFE); polytetrahydrofuran; polyethers (for example polyethylene glycol, polypropylene glycol); polyvinyl compounds, in particular polyvinyl chloride (PVC), PVC copolymers, PVdC, polyvinyl acetate as well as copolymers thereof, optionally partially hydrolyzed polyvinyl alcohol, polyvinyl acetals, polyvinyl acetates, polyvinyl pyrrolidone, polyvinyl ethers, polyvinyl acrylates and methacrylates in solution and as a dispersion as well as copolymers thereof, polyacrylates and polystyrene copolymers; polystyrene (modified or not to be shockproof); polyurethanes, uncrosslinked or crosslinked with isocyanates; polyurethane acrylate; styrene acrylic copolymers; styrene butadiene block copolymers (for example Styroflex® or Styrolux® from BASF AG, K-Resin™ from CPC); proteins, for example casein; SIS; triazine resin, bismaleimide triazine resin (BT), cyanate ester resin (CE), allylated polyphenylene ethers (APPE). Mixtures of two or more polymers may also form the matrix material.

Polymers particularly preferred as a matrix material are acrylates, acrylic resins, cellulose derivatives, methacrylates, methacrylic resins, melamine and amino resins, polyalkylenes, polyimides, epoxy resins, modified epoxy resins, for example bifunctional or polyfunctional Bisphenol A or Bisphenol F resins, epoxy-novolak resins, brominated epoxy resins, cycloaliphatic epoxy resins; aliphatic epoxy resins, glycidyl ethers, vinyl ethers and phenolic resins, polyurethanes, polyesters, polyvinyl acetals, polyvinyl acetates, polystyrenes, polystyrene copolymers, polystyrene acrylates, styrene butadiene block copolymers, alkenyl vinyl acetates and vinyl chloride copolymers, polyamides and copolymers thereof.

As a matrix material for the dispersion in the production of printed circuit boards, it is preferable to use thermally or radiation-curing resins, for example modified epoxy resins such as difunctional or polyfunctional Bisphenol A or Bisphenol F resins, epoxy-novolak resins, brominated epoxy resins, cycloaliphatic epoxy resins; aliphatic epoxy resins, glycidyl ethers, cyanate esters, vinyl ethers, phenolic resins, polyimides, melamine resins and amino resins, polyurethanes, polyesters and cellulose derivatives.

Expressed in terms of the total weight of the dry coating, the proportion of the organic binder components is preferably from 0.01 to 60 wt. %. The proportion is preferably from 0.1 to 45 wt. %, more preferably from 0.5 to 35 wt. %.

In order to be able to apply the dispersion containing the electrically-conductive particles and the matrix material onto the support, a solvent or a solvent mixture may furthermore be added to the dispersion in order to adjust the viscosity of the dispersion suitable for the respective application method. Suitable solvents are, for example, aliphatic and aromatic hydrocarbons (for example n-octane, cyclohexane, toluene, xylene), alcohols (for example methanol, ethanol, 1-propanol, 2-propanol, 1-butanol, 2-butanol, amyl alcohol), polyvalent alcohols such as glycerol, ethylene glycol, propylene glycol, neopentyl glycol, alkyl esters (for example methyl acetate, ethyl acetate, propyl acetate, butyl acetate, isobutyl acetate, isopropyl acetate, 3-methyl butanol), alkoxy alcohols (for example methoxypropanol, methoxybutanol, ethoxypropanol), alkyl benzenes (for example ethyl benzene, isopropyl benzene), butyl glycol, dibutyl glycol, alkyl glycol acetates (for example butyl glycol acetate, dibutyl glycol acetate), diacetone alcohol, diglycol dialkyl ethers, diglycol monoalkyl ethers, dipropylene glycol dialkyl ethers, dipropylene glycol monoalkyl ethers, diglycol alkyl ether acetates, dipropylene glycol alkyl ether acetate, dioxane, dipropylene glycol and ethers, diethylene glycol and ethers, DBE (dibasic esters), ethers (for example diethyl ether, tetrahydrofuran), ethylene chloride, ethylene glycol, ethylene glycol acetate, ethylene glycol dimethyl ester, cresol, lactones (for example butyrolactone), ketones (for example acetone, 2-butanone, cyclohexanone, methyl ethyl ketone (MEK), methyl isobutyl ketone (MIBK)), dimethyl glycol, methylene chloride, methylene glycol, methylene glycol acetate, methyl phenol (ortho-, meta-, para-cresol), pyrrolidones (for example N-methyl-2-pyrrolidone), propylene glycol, propylene carbonate, carbon tetrachloride, toluene, trimethylol propane (TMP), aromatic hydrocarbons and mixtures, aliphatic hydrocarbons and mixtures, alcoholic monoterpenes (for example terpineol), water and mixtures of two or more of these solvents.

Preferred solvents are alcohols (for example ethanol, 1-propanol, 2-propanol, butanol), alkoxyalcohols (for example methoxy propanol, ethoxy propanol, butyl glycol, dibutyl glycol), butyrolactone, diglycol dialkyl ethers, diglycol monoalkyl ethers, dipropylene glycol dialkyl ethers, dipropylene glycol monoalkyl ethers, esters (for example ethyl acetate, butyl acetate, butyl glycol acetate, dibutyl glycol acetate, diglycol alkyl ether acetates, dipropylene glycol alkyl ether acetates, DBE), ethers (for example tetrahydrofuran), polyvalent alcohols such as glycerol, ethylene glycol, propylene glycol, neopentyl glycol, ketones (for example acetone, methyl ethyl ketone, methyl isobutyl ketone, cyclohexanone), hydrocarbons (for example cyclohexane, ethyl benzene, toluene, xylene), N-methyl-2-pyrrolidone, water and mixtures thereof.

When the dispersion is applied onto the support using an inkjet method, alkoxy alcohols (for example ethoxy propanol, butyl glycol, dibutyl glycol) and polyvalent alcohols such as glycerol, esters (for example dibutyl glycol acetate, butyl glycol acetate, dipropylene glycol methyl ether acetates), water, cyclohexanone, butyrolactone, N-methyl-pyrrolidone, DBE and mixtures thereof are particularly preferred.

In the case of liquid matrix materials (for example liquid epoxy resins, acrylic esters), the respective viscosity may alternatively be adjusted via the temperature during application, or via a combination of a solvent and temperature.

The dispersion may furthermore contain a dispersant component. This consists of one or more dispersants.

In principle, all dispersants known to the person skilled in the art for application in dispersions and described in the prior art are suitable. Preferred dispersants are surfactants or surfactant mixtures, for example anionic, cationic, amphoteric or non-ionic surfactants.

Cationic and anionic surfactants are described, for example, in “Encyclopedia of Polymer Science and Technology”, J. Wiley & Sons (1966), Vol. 5, pp. 816-818, and in “Emulsion Polymerisation and Emulsion Polymers”, ed. P. Lovell and M. El-Asser, Wiley & Sons (1997), pp. 224-226.

Examples of anionic surfactants are alkali metal salts of organic carboxylic acids with chain lengths of from 8 to 30 C atoms, preferably from 12 to 18 C atoms. These are generally referred to as soaps. As a rule, they are used as sodium, potassium or ammonium salts. It is also possible to use alkyl sulfate and alkyl or alkylaryl sulfonates with from 8 to 30 C atoms, preferably from 12 to 18 C atoms, as anionic surfactants. Particularly suitable compounds are alkali metal dodecyl sulfates, for example sodium dodecyl sulfate or potassium dodecyl sulfate, and alkali metal salts of C₁₂-C₁₆ paraffin sulfonic acids. Sodium dodecyl benzene sulfate and sodium dodecyl sulfonic succinate are furthermore suitable.

Examples of suitable cationic surfactants are salts of amines or diamines, quaternary ammonium salts, for example hexadecyl trimethyl ammonium bromide, and salts of long-chained substituted cyclic amines, such as pyridine, morpholine, piperidine. Quaternary ammonium salts of trialkyl amines are used in particular, for example hexadecyl trimethyl ammonium bromide. The alkyl residues therein preferably comprise 1 to 20 C atoms.

In particular, non-ionic surfactants may be used as a dispersant component according to the invention. Non-ionic surfactants are described, for example, in the Römpp Chemie Lexikon CD—Version 1.0, Stuttgart/New York: Georg Thieme Verlag 1995, keyword “Nichtionische Tenside” [Non-ionic surfactants].

Suitable non-ionic surfactants are, for example, polyethylene oxide- or polypropylene oxide-based substances, such as Pluronic® or Tetronic® from BASF Aktiengesellschaft.

Polyalkylene glycols suitable as non-ionic surfactants generally have a number-average molecular weight Mₙ in the range of from 1000 to 15 000 g/mol, preferably from 2000 to 13 000 g/mol, particularly preferably from 4000 to 11 000 g/mol. Polyethylene glycols are preferred non-ionic surfactants.

Polyalkylene glycols are known per se or can be prepared according to methods which are known per se, for example by anionic polymerization with alkali metal hydroxides such as sodium or potassium hydroxide, or alkali metal alcoholates such as sodium methylate, sodium or potassium ethylate or potassium isopropylate as catalysts, and with the addition of at least one starter molecule which contains from 2 to 8, preferably from 2 to 6 bound reactive hydrogen atoms, or by cationic polymerization with Lewis acids such as antimony pentachloride, boron fluoride etherate or activated clay as catalysts, from one or more alkylene oxides having from 2 to 4 carbon atoms in the alkylene residue.

Suitable alkylene oxides are, for example, tetrahydrofuran, 1,2- or 2,3-butylene oxide, styrene oxide and preferably ethylene oxide and/or 1,2-propylene oxide. The alkylene oxides may be used individually, alternately in succession or as mixtures. Suitable starter molecules are for example: water, organic dicarboxylic acids such as succinic acid, adipic acid, phthalic acid or terephthalic acid, aliphatic or aromatic, optionally N-mono-, N,N- or N,N′-dialkyl substituted diamines having from 1 to 4 carbon atoms in the alkyl residue, such as optionally mono- and dialkyl substituted ethylene diamine, diethylene triamine, triethylene tetramine, 1,3-propylene diamine, 1,3- or 1,4-butylene diamine, 1,2-, 1,3-, 1,4-, 1,5- or 1,6-hexamethylene diamine.

Further suitable starter molecules are: alkanolamines, for example ethanolamine, N-methyl and N-ethyl ethanolamine, dialkanolamines, for example diethanolamine, N-methyl and N-ethyl diethanolamine, and trialkanolamines, for example triethanolamine, and ammonia. Polyvalent, in particular di-, trivalent or higher valent, alcohols such as ethandiol, 1,2- and 1,3-propandiol, diethylene glycol, dipropylene glycol, 1,4-butandiol, 1,6-hexandiol, glycerol, trimethylolpropane, pentaerythrite, and saccharoses, sorbite and sorbitol are preferably used.

Likewise suitable for the dispersant component are esterified polyalkylene glycols, for example the mono-, di-, tri- or polyesters of the said polyalkylene glycols, which can be prepared by reacting the terminal OH groups of the said polyalkylene glycols with organic acids, preferably adipic acid or terephthalic acid, in a manner which is known per se.

Non-ionic surfactants are substances prepared by alkoxylation of compounds with active hydrogen atoms, for example addition products of alkylene oxide to fatty alcohols, oxo alcohols or alkyl phenols. For example, ethylene oxide or 1,2-propylene oxide may be used for the alkoxylation.

Other possible non-ionic surfactants are alkoxylated or non-alkoxylated sugar esters or sugar ethers.

Sugar ethers are alkyl glycosides obtained by reacting fatty alcohols with sugars. Sugar esters are obtained by reacting sugars with fatty acids. The sugars, fatty alcohols and fatty acids needed for preparing the said substances are known to the person skilled in the art.

Suitable sugars are described, for example, in Beyer/Walter, Lehrbuch der organischen Chemie [Textbook of organic chemistry], S. Hirzel Verlag Stuttgart, 19^{th} edition, 1981, pp. 392 to 425. Possible sugars are D-sorbite and sorbitane which is obtained by dehydrating D-sorbite.

Suitable fatty acids are saturated or singly or multiply unsaturated, unbranched or branched carboxylic acids having from 6 to 26, preferably from 8 to 22, particularly preferably from 10 to 20 C atoms, as mentioned for example in the Römpp Chemie Lexikon CD, Version 1.0, Stuttgart/New York: Georg Thieme Verlag 1995, keyword “Fettsäuren” [Fatty acids]. The fatty acids which may be envisaged are lauric acid, palmitic acid, stearic acid and oleic acid.

Suitable fatty alcohols have the same carbon backbone as the compounds described as suitable fatty acids.

Sugar ethers, sugar ethers and the methods for preparing them are known to the person skilled in the art. Preferred sugar ethers are prepared according to known methods by reacting the said sugars with the said fatty alcohols. Preferred sugar esters are prepared according to known methods by reacting the said sugars with the said fatty acids. Suitable sugar esters are mono-, di- and triester of sorbitanes with fatty acids, in particular sorbitane monolaurate, sorbitane dilaurate, sorbitane trilaurate, sorbitane monooleate, sorbitane dioleate, sorbitane trioleate, sorbitane monopalmitate, sorbitane dipalmitate, sorbitane tripalmitate, sorbitane monostearate, sorbitane distearate, sorbitane tristearate and sorbitane sesquioleate, a mixture of sorbitane mono- and diesters of oleic acid.

Possible as dispersants are thus alkoxylated sugar ethers and sugar esters, which are obtained by alkoxylating the said sugar ethers and sugar esters. Preferred alkoxylating agents are ethylene oxide and 1,2-propylene oxide. The degree of alkoxylation is generally between 1 and 20, preferably 2 and 10, particularly preferably 2 and 6. Examples of this are polysorbates which are obtained by ethoxylating the sorbitan esters described above, for example as described in the Römpp Chemie Lexikon CD—Version 1.0, Stuttgart/New York: Georg Thieme Verlag 1995, keyword “Polysorbate” [Polysorbates]. Suitable polysorbates are polyethoxysorbitane laurate, stearate, palmitate, tristearate, oleate, trioleate, in particular polyethoxysorbitane stearate, which is available for example as Tween® 60 from ICI America Inc. (Described, for example, in the Römpp Chemie Lexikon CD—Version 1.0, Stuttgart/New York: Georg Thieme Verlag 1995, keyword “Tween®”).

It is likewise possible to use polymers as dispersants.

The dispersant may be used in the range of from 0.01 to 50 wt. %, expressed in terms of the total weight of the dispersion. The proportion is preferably from 0.1 to 25 wt. %, particularly preferably from 0.2 to 10 wt. %.

The dispersion according to the invention may furthermore contain a filler component. This may consist of one or more fillers. For instance, the filler component of the metallizable mass may contain fillers in fiber, layer or particle form, or mixtures thereof. These are preferably commercially available products, for example carbon and mineral fillers.

It is furthermore possible to use fillers or reinforcers such as glass powder, mineral fibers, whiskers, aluminum hydroxide, metal oxides such as aluminum oxide or iron oxide, mica, quartz powder, calcium carbonate, barium sulfate, titanium dioxide or wollastonite.

Other additives may furthermore be used, such as thixotropic agents, for example silica, silicates, for example aerosils or bentonites, or organic thixotropic agents and thickeners, for example polyacrylic acid, polyurethanes, hydrated castor oil, dyes, fatty acids, fatty acid amides, plasticizers, networking agents, defoaming agents, lubricants, desiccants, crosslinkers, photoinitiators, sequestrants, waxes, pigments, conductive polymer particles.

The proportion of the filler component is preferably from 0.01 to 50 wt. %, expressed in terms of the total weight of the dry coating. From 0.1 to 30 wt. % are further preferred, and from 0.3 to 20 wt. % are particularly preferred.

There may furthermore be processing auxiliaries and stabilizers in the dispersion according to the invention, such as UV stabilizers, lubricating agents, corrosion inhibitors and flame retardants. Their proportion is usually from 0.01 to 5 wt. %, expressed in terms of the total weight of the dispersion. The proportion is preferably from 0.05 to 3 wt. %.

After applying the structured or full-area base layer onto the support by using the dispersion which contains the electrically-conductive particles in the matrix material, and drying or curing the matrix material, the particles for the most part lie inside the matrix so that a continuous electrically-conductive surface has not been produced. In order to produce the continuous electrically-conductive surface, it is necessary for the structured or full-area base layer applied onto the support to be coated with an electrically-conductive material. This coating is generally carried out by electroless and/or electrolytic metallization.

In order to be able to coat the structured or full-area base layer electrolessly and/or electrolytically, it is first necessary to at least partially dry or cure the structured or full-area base layer produced by using the dispersion. Drying or curing of the structured or full-area surface is carried out according to customary methods. For example, the matrix material may be cured chemically, for example by polymerization, polyaddition or polycondensation of the matrix material, for example using UV radiation, electron radiation, microwave radiation, IR radiation or heat, or purely physically by evaporating the solvent. A combination of drying physically and chemically is also possible. After the at least partial drying or curing, according to the invention the electrically-conductive particles contained in the dispersion are at least partially exposed so that electrically-conductive nucleation sites are already obtained, onto which the metal ions can be deposited to form a metal layer during the subsequent electroless and/or electrolytic metallization. If the particles consist of materials which are readily oxidized, it is sometimes also necessary to remove the oxide layer at least partially beforehand. Depending on the way in which the method is carried out, for example by using acidic electrolyte solutions, the removal of the oxide layer may already take place simultaneously as the metallization is carried out, without an additional process step being necessary.

An advantage of exposing the particles before the electroless and/or electrolytic metallization is that in order to obtain a continuous electrically-conductive surface, by exposing the particles the coating only needs to contain a proportion of electrically-conductive particles which is about 5 to 10 wt. % lower than is the case when the particles are not exposed. Further advantages are the homogeneity and continuity of the coatings being produced and the high process reliability.

The electrically-conductive particles may be exposed either mechanically, for example by crushing, grinding, milling, sandblasting or blasting with supercritical carbon dioxide, physically, for example by heating, laser, UV light, corona or plasma discharge, or chemically. In the case of chemical exposure, it is preferable to use a chemical or chemical mixture which is compatible with the matrix material. In the case of chemical exposure, either the matrix material may be at least partially dissolved on the surface and washed away, for example by a solvent, or the chemical structure of the matrix material may be at least partially disrupted by means of suitable reagents so that the electrically-conductive particles are exposed. Reagents which make the matrix material tumesce are also suitable for exposing the electrically-conductive particles. The tumescence creates cavities which the metal ions to be deposited can enter from the electrolyte solution, so that a larger number of electrically-conductive particles can be metallized. The bonding, homogeneity and continuity of the metal layer subsequently deposited electrolessly and/or electrolytically is significantly better than in the methods described in the prior art. The process rate of the metallization is also higher because of the larger number of exposed electrically-conductive particles, so that additional cost advantages can be achieved.

If the matrix material is for example an epoxy resin, a modified epoxy resin, an epoxy-Novolak, a polyacrylate, ABS, a styrene-butadiene copolymer or a polyether, the electrically-conductive particles are preferably exposed by using an oxidant. The oxidant breaks bonds of the matrix material, so that the binder can be dissolved and the particles can thereby be exposed. Suitable oxidants are, for example, manganates such as for example potassium permanganate, potassium manganate, sodium permanganate, sodium manganate, hydrogen peroxide, oxygen, oxygen in the presence of catalysts such as for example manganese salts, molybdenum salts, bismuth salts, tungsten salts and cobalt salts, ozone, vanadium pentoxide, selenium dioxide, ammonium polysulfide solution, sulfur in the presence of ammonia or amines, manganese dioxide, potassium ferrate, dichromate/sulfuric acid, chromic acid in sulfuric acid or in acetic acid or in acetic anhydride, nitric acid, hydroiodic acid, hydrobromic acid, pyridinium dichromate, chromic acid-pyridine complex, chromic acid anhydride, chromium(VI) oxide, periodic acid, lead tetraacetate, quinone, methylquinone, anthraquinone, bromine, chlorine, fluorine, iron(III) salt solutions, disulfate solutions, sodium percarbonate, salts of oxohalic acids such as for example chlorates or bromates or iodates, salts of perhalic acids such as for example sodium periodate or sodium perchlorate, sodium perborate, dichromates such as for example sodium dichromate, salts of persulfuric acids such as potassium peroxodisulfate, potassium peroxomonosulfate, pyridinium chlorochromate, salts of hypohalic acids, for example sodium hypochloride, dimethyl sulfoxide in the presence of electrophilic reagents, tert-butyl hydroperoxide, 3-chloroperbenzoate, 2,2-dimethylpropanal, Des-Martin periodinane, oxalyl chloride, urea hydrogen peroxide adduct, urea hydrogen peroxide, 2-iodoxybenzoic acid, potassium peroxomonosulfate, m-chloroperbenzoic acid, N-methylmorpholine-N-oxide, 2-methylprop-2-yl hydroperoxide, peracetic acid, pivaldehyde, osmium tetraoxide, oxone, ruthenium(III) and (IV) salts, oxygen in the presence of 2,2,6,6-tetramethylpiperidinyl-N-oxide, triacetoxiperiodinane, trifluoroperacetic acid, trimethyl acetaldehyde, ammonium nitrate. The temperature during the process may optionally be increased in order to improve the exposure process.

Preferred oxidants are manganates, for example potassium permanganate, potassium manganate, sodium permanganate, sodium manganate, hydrogen peroxide, N-methylmorpholine-N-oxide, percarbonates, for example sodium or potassium percarbonate, perborates, for example sodium or potassium perborate, persulfates, for example sodium or potassium persulfate, sodium, potassium and ammonium peroxodi- and monosulfates, sodium hydrochloride, urea hydrogen peroxide adducts, salts of oxohalic acids such as for example chlorates or bromates or iodates, salts of perhalic acids such as for example sodium periodate or sodium perchlorate, tetrabutylammonium peroxidisulfate, quinone, iron(III) salt solutions, vanadium pentoxide, pyridinium dichromate, hydrochloric acid, bromine, chlorine, dichromates.

Particularly preferred oxidants are potassium permanganate, potassium manganate, sodium permanganate, sodium manganate, hydrogen peroxide and its adducts, perborates, percarbonates, persulfates, peroxodisulfates, sodium hypochloride and perchlorates.

In order to expose the electrically-conductive particles in a matrix material which contains for example ester structures such as polyester resins, polyester acrylates, polyether acrylates, polyester urethanes, it is preferable for example to use acidic or alkaline chemicals and/or chemical mixtures. Preferred acidic chemicals and/or chemical mixtures are, for example, concentrated or dilute acids such as hydrochloric acid, sulfuric acid, phosphoric acid or nitric acid. Organic acids such as formic acid or acetic acid may also be suitable, depending on the matrix material. Suitable alkaline chemicals and/or chemical mixtures are, for example, bases such as sodium hydroxide, potassium hydroxide, ammonium hydroxide or carbonates, for example sodium carbonate or calcium carbonate. The temperature during the process may optionally be increased in order to improve the exposure process.

Solvents may also be used to expose the electrically-conductive particles in the matrix material. The solvent must be adapted to the matrix material, since the matrix material must dissolve in the solvent or be tumesced by the solvent. When using a solvent in which the matrix material dissolves, the base layer is brought in contact with the solvent only for a short time so that the upper layer of the matrix material is solvated and thereby dissolved. In principle, all solvents mentioned above may be used. Preferred solvents are xylene, toluene, halogenated hydrocarbons, acetone, methyl ethyl ketone (MEK), methyl isobutyl ketone (MIBK), diethylene glycol monobutyl ether. The temperature during the dissolving process may optionally be increased in order to improve the dissolving behavior.

Furthermore, it is also possible to expose the electrically-conductive particles by using a mechanical method. Suitable mechanical methods are, for example, crushing, grinding, polishing with an abrasive or pressure blasting with a water jet, sandblasting or blasting with supercritical carbon dioxide. The top layer of the cured, printed structured base layer is respectively removed by such a mechanical method. The electrically-conductive particles contained in the matrix material are thereby exposed.

All abrasives known to the person skilled in the art may be used as abrasives for polishing. A suitable abrasive is, for example, pumice powder. In order to remove the top layer of the cured dispersion by pressure blasting with a water jet, the water jet preferably contains small solid particles, for example pumice powder (Al₂O₃) with an average particle size distribution of from 40 to 120 μm, preferably from 60 to 80 μm, as well as quartz powder (SiO₂) with a particle size >3 μm.

If the electrically-conductive particles contain a material which can readily oxidize, in a preferred method variant the oxide layer is at least partially removed before the metal layer is formed on the structured or full-area base layer. The oxide layer may in this case be removed chemically and/or mechanically, for example. Suitable substances with which the base layer can be treated in order to chemically remove an oxide layer from the electrically-conductive particles are, for example, acids such as concentrated or dilute sulfuric acid or concentrated or dilute hydrochloric acid, citric acid, phosphoric acid, amidosulfonic acid, formic acid, acetic acid.

Suitable mechanical methods for removing the oxide layer from the electrically-conductive particles are generally the same as the mechanical methods for exposing the particles.

So that the dispersion which is applied onto the support bonds firmly to the support, in a preferred embodiment the latter is cleaned by a dry method, a wet chemical method and/or a mechanical method before applying the structured or full-area base layer. By the wet chemical and mechanical methods, it is in particular also possible to roughen the surface of the support so that the dispersion bonds to it better. A suitable wet chemical method is, in particular, washing the support with acidic or alkaline reagents or with suitable solvents. Water may also be used in conjunction with ultrasound. Suitable acidic or alkaline reagents are, for example, hydrochloric acid, sulfuric acid or nitric acid, phosphoric acid, or sodium hydroxide, potassium hydroxide or carbonates such as potassium carbonate. Suitable solvents are the same as those which may be contained in the dispersion for applying the base layer. Preferred solvents are alcohols, ketones and hydrocarbons, which need to be selected as a function of the support material. The oxidants which have already been mentioned for the activation may also be used.

Mechanical methods with which the support can be cleaned before applying the structured or full-area base layer are generally the same as those which may be used to expose the electrically-conductive particles and to remove the oxide layer of the particles.

Dry cleaning methods in particular are suitable for removing dust and other particles which can affect the bonding of the dispersion on the support, and for roughening the surface. These are, for example, dust removal by means of brushes and/or deionized air, corona discharge or low-pressure plasma as well as particle removal by means of rolls and/or rollers, which are provided with an adhesive layer.

By corona discharge and low-pressure plasma, the surface tension of the substrate can be selectively increased, organic residues can be cleaned from the substrate surface, and therefore both the wetting with the dispersion and the bonding of the dispersion can be improved.

The structured or full-area base layer is preferably printed onto the support with any printing method by using the dispersion. The printing method with which it is possible to print on the structured surface is, for example, a roll or a sheet printing method such as for example screen printing, intaglio printing, flexographic printing, typography, pad printing, inkjet printing, the Lasersonic® method as described in DE10051850, or offset printing. Any other printing method known to the person skilled in the art may, however, also be used. It is also possible to apply the surface using another conventional and widely known coating method. Such coating methods are, for example, casting, painting, doctor blading, brushing, spraying, immersion, rolling, powdering, fluidized bed or the like. Thickness of the structured or full-area surface produced by printing or the coating method preferably varies between 0.01 and 50 μm, more preferably between 0.05 and 25 μm and particularly preferably between 0.1 and 15 μm. The layers may be applied either surface-wide or in a structured way.

Differently fine structures can be printed, depending on the printing method.

The dispersion is preferably stirred or pumped around in a storage container before application. Stirring and/or pumping prevents possible sedimentation of the particles contained in the dispersion. Furthermore, it is likewise advantageous for the dispersion to be thermally regulated in the storage container. This makes it possible to achieve an improved printing impression of the base layer on the support, since a constant viscosity can be adjusted by thermal regulation. Thermal regulation is necessary in particular whenever, for example, the dispersion is heated by the energy input of the stirrer or pump when stirring and/or pumping and its viscosity therefore changes.

In order to increase the flexibility and for cost reasons, digital printing methods such as inkjet printing and the LaserSonic® method are particularly suitable in the case of a printing application. These methods generally obviate the costs for the production of printing templates, for example printing rolls or screens, as well as their constant changing when a plurality of different structures need to be printed successively. In digital printing methods, it is possible to change over to a new design immediately, without refitting times and stoppages.

In the case of applying the dispersion by means of inkjet methods, it is preferable to use electrically-conductive particles with a maximum size of 15 μm, particularly preferably 10 μm, in order to prevent clogging the inkjet nozzles. In order to avoid sedimentation in the inkjet head, the dispersion may be pumped by means of a pumping circuit so that the particles do not settle. It is furthermore advantageous if the system can be heated, in order to adjust the viscosity of the dispersion suitably for printing.

Besides applying the dispersion onto one side of the support, with the method according to the invention it is also possible to provide the support with an electrically-conductive structured or full-area base layer on its upper side and its lower side. With the aid of vias, the structured or full-area electrically-conductive base layers on the upper side and the lower side of the support can be electrically connected to one another. For via contacting, for example, a wall of a bore in the support is provided with an electrically-conductive surface. In order to produce the via, it is possible to form bores in the support, for example, onto the walls of which the dispersion that contains the electrically-conductive particles is applied when printing the structured or full-area base layer. For a sufficiently thin support, it is not necessary to coat the wall of the bore with the dispersion since, with a sufficiently long coating time, a metal layer also forms inside the bore during the electroless and/or electrolytic coating by the metal layers growing together into the bore from the upper and lower sides of the support, so as to create electrical connection of the electrically-conductive structured or full-area surfaces on the upper and lower sides of the support. Besides the method according to the invention, it is also possible to use other methods known from the prior art for metallizing bores and/or blind holes.

In order to obtain a mechanically stable structured or full-area base layer on the support, it is preferable for the dispersion, using which the structured or full-area base layer is applied onto the support, to be at least partially cured after application. Depending on the matrix material, the curing is carried out as described above for example by the action of heat, light (UV/Vis) and/or radiation, for example infrared radiation, electron radiation, gamma radiation, X-radiation, microwaves. In order to initiate the curing reaction, it may sometimes be necessary to add a suitable activator. The curing may also be achieved by a combination of different methods, for example by a combination of UV radiation and heat. The curing methods may be combined simultaneously or successively. For example, the layer may first be only partially cured by UV radiation, so that the structures formed no longer flow apart. The layer may subsequently be cured by the action of heat. The heating may in this case take place directly after the UV curing and/or after the electrolytic metallization. After the at least partial curing—as already described above—in a preferred variant the electrically-conductive particles are at least partially exposed. In order to produce the continuous electrically-conductive surface, at least one metal layer is formed by electroless and/or electrolytic coating on the structured or full-area base layer after exposing the electrically-conductive particles. The coating may in this case be carried out using any method known to the person skilled in the art. Any conventional metal coating may moreover be applied using the coating method. In this case, the composition of the electrolyte solution, which is used for the coating, depends on the metal with which the electrically-conductive structures on the substrate are intended to be coated. In principle, all metals which are nobler than or equally noble as the least noble metal of the dispersion may be used for the electroless and/or electrolytic coating. Conventional metals which are deposited onto electrically-conductive surfaces by electrolytic coating are, for example, gold, nickel, palladium, platinum, silver, tin, copper or chromium. The thicknesses of the one or more deposited layers lie in the conventional range known to the person skilled in the art, and are not essential to the invention.

Suitable electrolyte solutions, which are used for coating electrically-conductive structures, are known to the person skilled in the art for example from Werner Jiliek, Gustl Keller, Handbuch der Leiterplattentechnik [Handbook of printed circuit technology]. Eugen G. Leuze Verlag, 2003, volume 4, pages 332-352.

In order to coat the electrically-conductive structured or full-area surface on the support, the support is first sent to the bath containing the electrolyte solution. The support is then transported through the bath, electrically-conductive particles contained in the previously applied structured or full-area base layer being contacted by at least one cathode. Here, any suitable conventional cathode known to the person skilled in the art may be used. As long as the cathode contacts the structured or full-area surface, metal ions are deposited from the electrolyte solution to form a metal layer on the surface.

A suitable device, in which the structured or full-area electrically-conductive base layer can be electrolytically coated, generally comprises at least one bath, one anode and one cathode, the bath containing an electrolyte solution containing at least one metal salt. Metal ions from the electrolyte solution are deposited on electrically-conductive surfaces of the substrate to form a metal layer. To this end, the at least one cathode is brought in contact with the substrate's base layer to be coated while the substrate is transported through the bath.

All electrolytic methods known to the person skilled in the art are suitable for the electrolytic coating in this case. Such electrolytic methods, for example, are those in which the cathode is formed by one or more rollers which contact the material to be coated. The cathodes may also be designed in the form of segmented rollers, in which at least the roller segment which is in communication with the substrate to be coated is respectively connected cathodically. So that the deposited metal on the roller can be removed again, in the case of segmented rollers it is possible to anodically connect the segments which do not contact the base layer to be coated, so that the metal deposited on them is deposited back into the electrolyte solution.

In one embodiment, the at least one cathode comprises at least one band having at least one electrically-conductive section, which is guided around at least two rotatable shafts. The shafts are configured with a suitable cross section adapted to the respective substrate. The shafts are preferably designed cylindrically and may, for example, be provided with grooves in which the at least one band runs. For electrical contacting of the band, at least one of the shafts is preferably connected cathodically, the shaft being configured so that the current is transmitted from the surface of the shaft to the band. When the shafts are provided with grooves in which the at least one band runs, the substrate can be contacted simultaneously via the shafts and the band. Nevertheless, it is also possible for only the grooves to be electrically-conductive and for the regions of the shafts between the grooves to be made of an insulating material, so as to prevent the substrate from being electrically contacted via the shafts as well. The current supply of the shafts takes place via sliprings, for example, although it is also possible to use any other suitable device with which current can be transmitted to rotating shafts.

Since the cathode comprises at least one band having at least one electrically-conductive section, it is possible even for substrates with short electrically-conductive structures, especially as seen in the transport direction of the substrate, to be provided with a sufficiently thick coating. This is possible since owing to the configuration of the cathode as a band, even short electrically-conductive structures stay in contact with the cathode for a longer time.

So that it is also possible to coat regions of the electrically-conductive structure on which the cathode configured as a band rests for contacting, at least two bands are preferably arranged offset in series. The arrangement is in this case generally such that the second band, arranged offset behind the first band, contacts the electrically-conductive structure in the region on which the metal was deposited when contacting with the first band. A larger thickness of the coating can be achieved by configuring more than two bands in series.

A construction which is shorter, as seen in the transport direction, can be achieved in that the respectively successive bands arranged offset are guided via at least one common shaft.

The at least one band may for example also have a network structure, so that only small regions of the electrically-conductive structures to be coated on the substrate are respectively covered by the band. The coating takes place in the holes of the network. So that it is also possible to coat the electrically-conductive structures in the regions in which the network rests, even for the case in which the bands are designed in the form of a network structure it is advantageous to arrange at least two bands respectively offset in series.

It is also possible for the at least one band to alternately comprise conductive sections and nonconductive sections. In this case, it is possible for the band to be additionally guided around at least one anodically connected shaft, although care should be taken that the length of the conductive sections is less than the distance between a cathodically connected shaft and a neighboring anodically connected shaft. In this way, the regions of the band which are in contact with the substrate to be coated are connected cathodically, and the regions of the band which are not in contact with the substrate are connected anodically. The advantage of this connection is that metal which deposits on the band during the cathodic connection of the band is removed again during the anodic connection. In order to remove all metal which has deposited on the band while it was connected cathodically, the anodically connected region is preferably longer than or at least equally as long as the cathodically connected region. This may be achieved on the one hand in that the anodically connected shaft has a greater diameter than the cathodically connected shafts, and on the other hand, with an equal or smaller diameter of the anodically connected shafts, it is possible to provide at least as many of them as cathodically connected shafts, the spacing of the cathodically connected shafts and the spacing of the anodically connected shafts preferably being of equal size.

Alternatively, instead of the bands, it is also possible for the cathode to comprise at least two disks mounted on a respective shaft so that they can rotate, the disks engaging in one another. This also makes it possible for electrically-conductive structures which are short, especially as seen in the transport direction of the substrate, to be provided with a sufficiently thick and homogeneous coating. The disks are generally configured with a cross section adapted to the respective substrate. The disks preferably have a circular cross section. The shafts may have any cross section. However, the shafts are preferably designed cylindrically.

In order to be able to coat structures which are wider than two adjacent disks, a plurality of disks are arranged next to one another on each shaft as a function of the width of the substrate. A sufficient distance is respectively provided between the individual disks, into which the disks of the subsequent shaft can engage. In a preferred embodiment, the distance between two disks on a shaft corresponds at least to the width of a disk. This makes it possible for a disk of a further shaft to engage into the distance between two disks on a shaft.

The current supply of the disks takes place, for example, via the shaft. In this way, for example, it is possible to connect the shaft to a voltage source outside the bath. This connection is generally carried out via a slipring. Nevertheless, any other connection with which a voltage transmission is transmitted from a stationary voltage source to a rotating element is possible. Besides the voltage supply via the shaft, it is also possible to supply the contact disks with current via their outer circumference. For example, sliding contacts such as brushes may lie in contact with the contact disks on the other side from the substrate.

In order to supply the disks with current via the shafts, for example, the shafts and the disks are preferably made at least partly of an electrically-conductive material. Besides this, however, it is also possible to make the shafts from an electrically insulating material and for the current supply to the individual disks to be produced for example through electrical conductors, for example wires. In this case, the individual wires are then respectively connected to the contact disks so that the contact disks are supplied with voltage.

In a preferred embodiment, the disks have individual sections, electrically insulated from one another, distributed over the circumference. The sections electrically insulated from one another can preferably be connected both cathodically and anodically. It is thereby possible for a section which is in contact with the substrate to be connected cathodically and, as soon as it is no longer in contact with the substrate, connected anodically. In this way, metal deposited on the section during the cathodic connection is removed again during the anodic connection. The voltage supply of the individual segments generally takes place via the shaft.

Other cleaning variants are also possible besides removing the metal deposited on the shaft and the disks, or the bands, by reversing the polarity of the shafts, or the bands, for example chemical or mechanical cleaning.

The material from which the electrically-conductive parts of the disks, or the bands, are made is preferably an electrically-conductive material which does not pass into the electrolyte solution during operation of the device. Suitable materials are for example metals, coated metals, graphite, conductive polymers such as polythiophenes or metal/plastic composite materials. Stainless steel and/or titanium, coated titanium such as iridium, tantalum, ruthenium mixed oxide-coated titanium or platinum-coated titanium are preferred materials.

It is also possible for a plurality of baths with different electrolyte solutions to be connected in series, so as to deposit a plurality of different metals on the base layer to be coated. Furthermore, it is also possible to deposit metal on the base layer first electrolessly and then electrolytically. In this case, different metals or the same metal may be deposited by the electroless and electrolytic deposition.

The electrolytic coating device may furthermore be equipped with a device by which the substrate can be rotated. The rotation axis of the device, by which the substrate can be rotated, is in this case arranged perpendicularly to the substrate's surface to be coated. Electrically-conductive structures which are initially wide and short as seen in the transport direction of the substrate, are aligned by the rotation so that they are narrow and long as seen in the transport direction after the rotation.

The layer thickness of the metal layer deposited on the electrically-conductive structure by the method according to the invention depends on the contact time, which is given by the speed with which the substrate passes through the device and the number of cathodes positioned in series, as well as the current strength with which the device is operated. A longer contact time may be achieved, for example, by connecting a plurality of devices according to the invention in series in at least one bath.

In order to permit simultaneous coating of the upper and lower sides, two rollers or two shafts with the disks mounted on them, or two bands, for example, may respectively be arranged so that the substrate to be coated can be guided through between them.

When the intention is to coat foils whose length exceeds the length of the bath—so-called endless foils which are first unwound from a roll, guided through the electrolytic coating device and then wound up again—they may for example also be guided through the bath in a zigzag shape or in the form of a meander around a plurality of electrolytic coating devices, which for example may then also be arranged above one another or next to one another.

The electrolytic coating device may, according to requirements, be equipped with any auxiliary device known to the person skilled in the art. Such auxiliary devices are, for example, pumps, filters, supply instruments for chemicals, winding and unwinding instruments etc.

All methods of treating the electrolyte solution known to the person skilled in the art may be used in order to shorten the maintenance intervals. Such treatment methods, for example, are also systems in which the electrolyte solution self-regenerates.

The device according to the invention may also be operated, for example, in the pulse method known from Werner Jiliek, Gustl Keller, Handbuch der Leiterplattentechnik [Handbook of printed circuit technology], Eugen G. Leuze Verlag, volume 4, pages 192, 260, 349, 351, 352, 359.

After applying the structured and/or full-area electrically-conductive surfaces of the first plane, an insulating layer is applied at the positions where conductor tracks of a second electrically-conductive surface cross over the conductor tracks of the first structured electrically-conductive surface and no contact is intended to take place between the first and second surfaces. The insulating layer is preferably applied by a printing or coating method. Suitable coating methods for applying the insulating layer are the same printing method's as have already been described above for printing on the first structured and/or full-area surface with the paste containing the electrically-conductive particles. The insulating layer is preferably printed onto the support by any printing method. Preferred printing methods are intaglio printing, flexographic printing, offset printing, screen printing, inkjet printing or pad printing. In particular for producing fine structures, for example the production of printed circuit boards, the inkjet printing method is suitable. It is also possible to apply the surface using another conventional and widely known coating method. Such coating methods are, for example, casting, painting, doctor blading, brushing, spraying, immersion, rolling, powdering, fluidized bed or the like.

For example, binders with a pigment-affine anchor group, natural and synthetic polymers and derivatives thereof, natural resins as well as synthetic resins and derivatives thereof, natural rubber, synthetic rubber, proteins, cellulose derivatives, drying and non-drying oils etc. are suitable as a material for the insulating layer. They may—but need not—be chemically or physically curing, for example air-curing, radiation-curing or temperature-curing.

The material for the insulating layer is preferably a polymer or polymer blend.

Polymers preferred as a material for the insulating layer are, for example, ABS (acrylonitrile-butadiene-styrene); ASA (acrylonitrile-styrene acrylate); acrylic acrylates; alkyd resins; alkyl vinyl acetates; alkyl vinyl acetate copolymers, in particular methylene vinyl acetate, ethylene vinyl acetate, butylene vinyl acetate; alkylene vinyl chloride copolymers; amino resins; aldehyde and ketone resins; celluloses and cellulose derivatives, in particular hydroxyalkyl celluloses, cellulose esters such as acetates, propionates, butyrates, carboxyalkyl celluloses, cellulose nitrate; epoxy acrylate; epoxy resins; ethylene-acrylic acid copolymers; hydrocarbon resins; MABS (transparent ABS also containing acrylate units); melamine resins, maleic acid anhydride copolymers; methacrylates; natural rubber; synthetic rubber; chlorine rubber; natural resins; colophonium resins; shellac; phenolic resins; polyesters; polyester resins such as phenyl ester resins; polysulfones; polyether sulfones; polyamides; polyimides; polyanilines; polypyrroles; polybutylene terephthalate (PBT); polycarbonate (for example Makrolon® from Bayer AG); polyester acrylates; polyether acrylates; polyethylene; polyethylene thiophene; polyethylene naphthalates; polyethylene terephthalate (PET); polyethylene terephthalate glycol (PETG); polypropylene; polymethyl methacrylate (PMMA); polyphenylene oxide (PPO); polytetrafluoroethylene (PTFE); polytetrahydrofuran; polyethers (for example polyethylene glycol, polypropylene glycol); polyvinyl compounds, in particular polyvinyl chloride (PVC), PVC copolymers, PVdC, polyvinyl acetate as well as copolymers thereof, optionally partially hydrolyzed polyvinyl alcohol, polyvinyl acetals, polyvinyl acetates, polyvinyl pyrrolidone, polyvinyl ethers, polyvinyl acrylates and methacrylates in solution and as a dispersion as well as copolymers thereof, polyacrylates and polystyrene copolymers; polystyrene (modified or not to be shockproof); polyurethanes, uncrosslinked or crosslinked with isocyanates; polyurethane acrylate; styrene acrylic copolymers; styrene butadiene block copolymers (for example Styroflex® or Styrolux® from BASF AG, K-Resin™ from CPC); proteins, for example casein; SIS; SPS block copolymers. Mixtures of two or more polymers may also form the material for the insulating layer.

Polymers particularly preferred as a material for the insulating layer are acrylates, acrylic resins, cellulose derivatives, methacrylates, methacrylic resins, melamine and amino resins, polyalkylenes, polyimides, epoxy resins, modified epoxy resins, for example bifunctional or polyfunctional Bisphenol A or Bisphenol F resins, epoxy-novolak resins, brominated epoxy resins, cycloaliphatic epoxy resins; aliphatic epoxy resins, glycidyl ethers, vinyl ethers and phenolic resins, polyurethanes, polyesters, polyvinyl acetals, polyvinyl acetates, polystyrenes, polystyrene copolymers, polystyrene acrylates, styrene butadiene block copolymers, alkenyl vinyl acetates and vinyl chloride copolymers, polyamides and copolymers thereof.

As a matrix material for the insulating layer in the production of printed circuit boards, it is preferable to use thermally or radiation-curing resins, for example modified epoxy resins such as difunctional or polyfunctional Bisphenol A or Bisphenol F resins, epoxy-novolak resins, brominated epoxy resins, cycloaliphatic epoxy resins; aliphatic epoxy resins, glycidyl ethers, cyanate esters, vinyl ethers, phenolic resins, polyimides, melamine resins and amino resins, polyurethanes, polyesters and cellulose derivatives.

In a preferred embodiment, the material for the insulating layer is the same as the matrix material of the first structured electrically-conductive surface.

After applying the insulating layer, the structured and/or full-area electrically-conductive surface of the second plane is applied. The application of the structured and/or full-area electrically-conductive surface of the second plane corresponds to the application of the structured and/or full-area electrically-conductive surface of the first plane.

After applying the structured and/or full-area electrically-conductive surface of the second plane, it is possible to apply further insulating layers and structured and/or full-area electrically-conductive surfaces of further planes onto the support, respectively in alternation.

The method according to the invention for producing electrically-conductive, structured or full-area surfaces on a support may be operated in a continuous, semicontinuous or discontinuous mode. It is also possible for only individual steps of the method to be carried out continuously, while other steps are carried out discontinuously.

An advantage of the method according to the invention in the production of printed circuit boards is that, for multilayer printed circuit boards, a smaller number of inner layers is needed since a larger number of conductor tracks and interconnections can be produced on a defined area. Since the individual layers are laminated with one another according to the prior art, the omission of layers also reduces the required number of laminating steps. If all the conductor tracks can be applied on a support by the method according to the invention, it is even possible that no laminating step at all is required any more.

The method according to the invention also reduces the number of bores in the printed circuit boards, which are needed in order to contact conductor tracks in various layers. Depending on the design of the printed circuit boards, it is even possible that no bores at all are required any more. It is also possible that only bores which serve as mounting holes are still required, while no bores are required any more through which conductor tracks on a plurality of layers are electrically contacted with one another.

Another advantage is also that the amount of insulation material can be reduced. For instance, according to the prior art it is necessary for an insulation material to be applied surface-wide between the individual multilayer inner layers. This insulation material comprises for example glass fabric, resin or prepregs. As a function of the design of the printed circuit boards, these interlayers are completely obviated so that only the support remains as a single support for all the circuit planes.

By reducing the layers, a flatter end product is furthermore obtained.

It is also possible to combine a conventional method for producing structured surfaces with the method according to the invention. For example, the support may be produced first by a conventional method, for example a resistible etching method, for example a resist or etching method. The structured and/or conductive surface produced by the conventional method on the support may subsequently be processed further by the method according to the invention. As a next step, after producing the first structured and/or conductive surface on the support, the insulating layer is applied and then a conductive printing paste is applied. Subsequent to this, the printing paste is dried and/or cured and then optionally coated electrolessly and/or electrolytically.

The method according to the invention allows inexpensive production of printed circuit boards on an electrically nonconductive substrates. The method according to the invention is also a flexible method, so that faster layout variation is possible.

The method according to the invention is suitable, for example, for producing conductor tracks on printed circuit boards. Such printed circuit boards are, for example, those with multilayer inner and outer levels, micro-vias, chip-on-boards, flexible and rigid printed circuit boards, and are for example installed in products such as computers, telephones, televisions, electrical automobile components, keyboards, radios, video, CD, CD-ROM and DVD players, game consoles, measuring and regulating equipment, sensors, electrical kitchen appliances, electrical toys etc.

Electrically-conductive structures on flexible circuit supports may also be coated with the method according to the invention. Such flexible circuit supports are, for example, plastic films made of the materials mentioned above for the supports, onto which electrically-conductive structures are printed. The method according to the invention is furthermore suitable for producing RFID antennas, transponder antennas or other antenna structures, chip card modules, flat cables, seat heaters, foil conductors, conductor tracks in solar cells or in LCD/plasma screens, capacitors, foil capacitors, resistors, convectors or electrical fuses. 3D molded interconnected devices, for example, may also be produced by the method according to the invention.

It is furthermore possible to produce antennas with contacts for organic electronic components, as well as coatings on surfaces consisting of electrically-nonconductive material for electromagnetic shielding.

Use is furthermore possible in the context of flow fields of bipolar plates for application in fuel cells.

The application range of the method according to the invention allows inexpensive production of metallized substrates which are nonconductive per se, particularly for use as switches and sensors, gas barriers or decorative parts, in particular decorative parts for the motor vehicle, sanitary, toy, household and office sectors, and packaging as well as foils. The invention may also be applied in the field of security printing for banknotes, credit cards, identity documents etc. Textiles may be electrically and magnetically functionalized with the aid of the method according to the invention (antennas, transmitters, RFID and transponder antennas, sensors, heating elements, antistatic (even for plastics), shielding etc.).

It is furthermore possible to produce contact points or contact pads or interconnections on an integrated electronic component.

Preferred uses of the substrate surfaces metallized according to the invention are those in which the substrate produced in this way is used as a printed circuit board, RFID antenna, transponder antenna, seat heater, flat cable, foil conductor, conductor tracks in solar cells or in LCD/plasma screens or as decorative application, for example for packaging materials.

After the electrolytic coating, the substrate may be processed further according to all steps known to the person skilled in the art. For example, remaining electrolyte residues may be removed from the substrate by washing and/or the substrate may be dried. Likewise, for example, the multilayer inner layers produced by the method according to the invention may be processed to form multilayer printed circuit boards. Furthermore, for example, holes, vias, blind holes etc. may subsequently be applied and metallized in printed circuit boards with the aim of providing contact between the upper and lower printed circuit board sides.

An advantage of the method according to the invention is that sufficient coating is possible even when using materials that readily oxidize for the electrically-conductive particles.

The invention will be described in more detail below with the aid of a drawing. All the figures only show one possible embodiment by way of example. Other than in the embodiments mentioned, the invention may naturally also be implemented in further embodiments or in a combination of these embodiments.

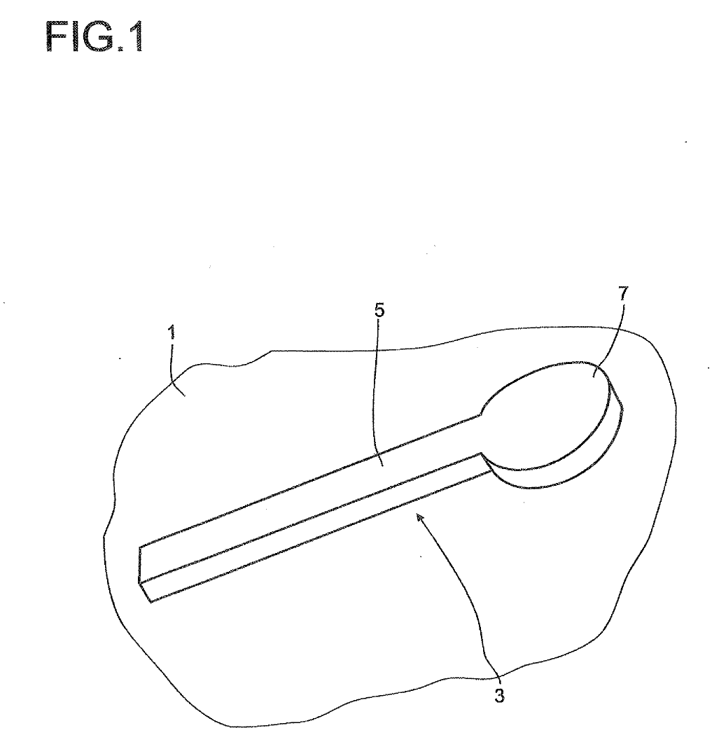

FIG. 1 shows a 3D representation of a structured electrically-conductive surface of a first layer,

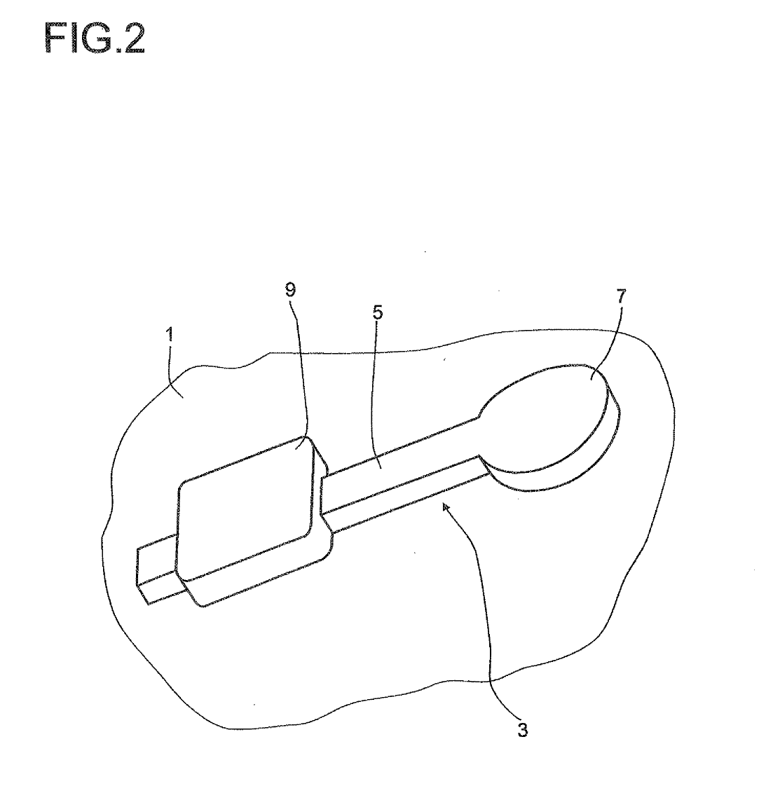

FIG. 2 shows a 3D representation of the structured electrically-conductive surface according to FIG. 1 with an insulating layer,

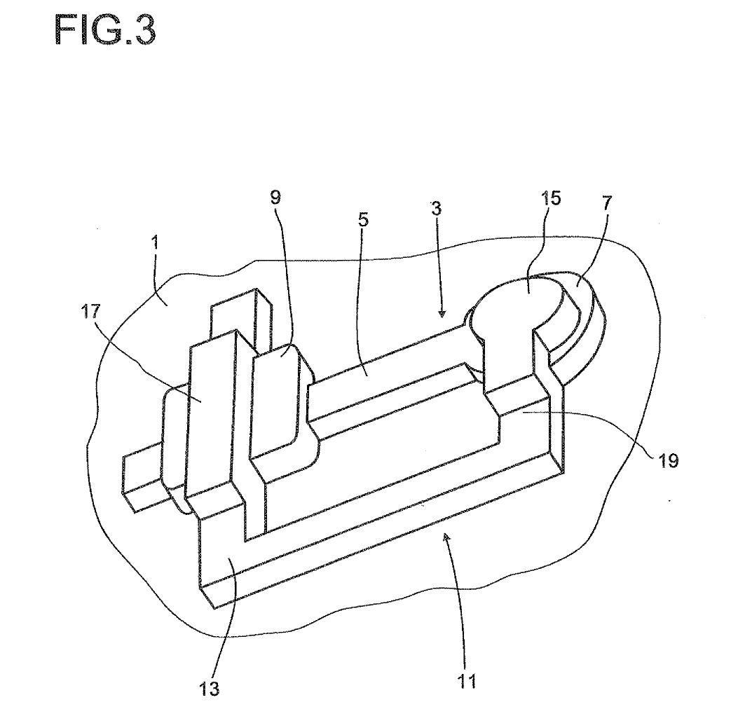

FIG. 3 a 3D representation according to FIG. 2 with an additional electrically-conductive surface of a second plane,

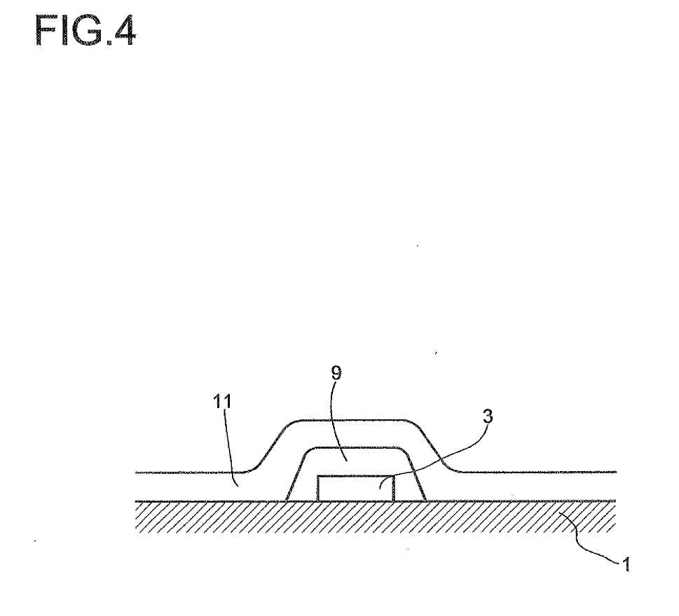

FIG. 4 a section or representation of two electrically-conductive surfaces crossing over one another, with an insulating layer between them.

FIG. 1 shows by way of example in 3D representation a detail of a support 1, on which a structured electrically-conductive surface 3 of a first plane is applied. The structured electrically-conductive surface of the first plane, represented here by way of example, comprises a conductor track 5 and a contact surface 7 on which the structured electrically-conductive surface 3 of the first plane can be contacted with a structured electrically-conductive surface of a further plane.

The structured electrically-conductive surface 3 of the first plane is preferably applied as above onto the support 1. The structured electrically-conductive surface 3 of the first plane is preferably applied onto the support 1 by a first printing on the structured electrically-conductive surface 3 with a paste, which contains electrically-conductive particles in a matrix material, and then exposing the particles at least partially and subsequently providing them with a metal layer by electroless and/or electrolytic coating.

After applying the structured electrically-conductive surface 3 of the first plane, an insulating layer 9 is applied as represented in FIG. 2. In the embodiment represented here, the insulating layer 9 covers a part of the conductor track 5 of the structured electrically-conductive surface 3. The insulating layer 9 is applied at a position where the conductor track 5 of the structured electrically-conductive surface 3 of the first plane is crossed by a conductor track of the structured electrically-conductive surface of a further plane. The insulating layer 9 is applied as described above. The insulating layer 9 is preferably printed on.

After applying the insulating layer, a structured electrically-conductive surface 11 of a second plane is applied as represented by way of example in FIG. 3. The structured electrically-conductive surface 11 of the second plane also comprises a conductor tracks 13 and a contact surface 15. In the exemplary embodiment three-dimensionally represented here, the conductor track 13 of the structured electrically-conductive surface 11 of the second plane has a U-shaped configuration. A first branch 17 of the U-shaped conductor track crosses the conductor track 5 of the structured electrically-conductive surface 3 of the first plane at the position where the insulating layer 9 was applied. The second branch 19 ends with the contact surface 15 at the position where the contact surface 7 of the structured electrically-conductive surface 3 of the first plane lies. The contact surface 15 of the structured electrically-conductive surface 11 of the second plane and the contact surface 7 of the structured electrically-conductive surface 3 of the first plane are in contact with one another, so that current can be transmitted from the structured electrically-conductive surface 3 of the first plane to the structured electrically-conductive surface 11 of the second plane via contact surfaces 7, 15. The contact surfaces 7, 15 are preferably designed so that the cross-sectional area of the lower contact surface, here the contact surface 7 of the first plane, is greater than the cross-sectional area of the upper contact surface, here the contact surface 15 of the second plane. In order to avoid a short circuit, at the position where the second branch 17 of the U-shaped conductor track 13 of the structured electrically-conductive surface 11 of the second plane crosses the conductor track 5 of the structured electrically-conductive surface 3 of the first plane, the insulating layer 9 is formed so that it lies between the conductor track 5 of the structured electrically-conductive surface 3 of the first plane and the conductor track 13 of the structured electrically-conductive surface 11 of the second plane.

The structured electrically-conductive surface 11 of the second plane is preferably applied in the same way as the structured electrically-conductive surface 3 of the first plane. It is however also possible to apply the first plane by a conventional method, for example an etching method, and the second plane by the method according to the invention. It is furthermore possible to apply the structured electrically-conductive surfaces of the individual planes are different methods.

FIG. 4 shows a sectional view of a support 1, on which a structured electrically-conductive surface 3 of a first plane and a structured electrically-conductive surface 11 of a second plane cross. So that no current is transferred from the structured electrically-conductive surface 3 of the first plane onto the structured electrically-conductive surface 11 of the second plane, an insulating layer 9 is formed between the structured electrically-conductive surfaces 3, 11.

1.-22. (canceled)

23. A method for producing structured and/or full-area electrically-conductive surfaces (3, 11) on an electrically nonconductive support (1), which comprises the following steps:
a) applying the structured and/or full-area electrically-conductive surfaces (3) of a first plane onto the electrically nonconductive support (1),
b) applying an insulating layer (9) at the positions where structured and/or full-area electrically-conductive surfaces (11) of a second plane cross the structured and/or full-area electrically-conductive surfaces (3) of the first plane and no electrical contact is intended to take place between the structured and/or fall-area electrically-conductive surfaces of the first plane (3) and of the second plane (11),
c) applying the structured and/or full-area electrically-conductive surfaces (11) of the second plane according to step a),
d) optionally repeating steps b) and c),
wherein the structured and/or full area electrically-conductive surfaces have a layer thickness in the range from 0.05 to 25 μm.

24. The method as claimed in claim 23, wherein the structured and/or full-area electrically-conductive surface is applied in step a) by a base layer first being applied with a dispersion, which contains electrically-conductive particles in a matrix material, and at least partially cured and/or dried, then the particles being at least partially exposed and subsequently provided with a metal layer by electroless and/or electrolytic coating.

25. The method as claimed in claim 24, wherein the electrically-conductive particles are exposed chemically, physically or mechanically.

26. The method as claimed in claim 24, wherein the electrically-conductive particles are exposed with an oxidant.

27. The method as claimed in claim 26, wherein the oxidant is potassium permanganate, potassium manganate, sodium permanganate, sodium manganate, hydrogen peroxide or its adducts, sodium perborate, sodium percarbonate, sodium persulfate, sodium peroxodisulfate, sodium hypochloride or sodium perchlorate.

28. The method as claimed in claim 23, wherein the electrically-conductive particles are exposed by the action of substances which can dissolve, etch and/or tumesce the matrix material.

29. The method as claimed in claim 28, wherein the substance which can dissolve, etch and/or tumesce the matrix material is an acidic or alkaline chemical or chemical mixture or a solvent.

30. The method as claimed in claim 24, wherein any existing oxide layer is removed from the electrically-conductive particles before the electroless and/or electrolytic coating of the structured or full-area base layer.

31. The method as claimed in claim 23, wherein the support is cleaned by a wet chemical method and/or a mechanical method before the structured and/or full-area electrically-conductive surface is applied.

32. The method as claimed in claim 31, wherein the dry method is dedusting by brushing and/or deionized air, low-pressure plasma, corona discharge or particle removal by rolls or rollers provided with an adhesive layer, the wet chemical method is washing with an acidic or alkaline chemical or chemical mixture or a solvent, and the mechanical method is brushing, grinding, polishing or pressure blasting with an air or water jet optionally containing particles.

33. The method as claimed in claim 23, wherein the material for the insulating layer is a polymer or a polymer mixture.

34. The method as claimed in claim 23, wherein the base layer is applied by a coating method.

35. The method as claimed in claim 23, wherein the base layer is printed onto the support by any printing method, preferably an inkjet printing method, a roll printing method, a screen printing method, a pad printing method or an offset printing method.

36. The method as claimed in claim 23, wherein the insulating layer is printed onto the support by any printing method, preferably an inkjet printing method, a roll printing method, a screen printing method, a pad printing method or an offset printing method.

37. The method as claimed in claim 23, wherein the insulating layer is at least partially dried and/or at least partially cured physically and/or chemically after application.

38. The method as claimed in claim 23, wherein the structured and/or full-area electrically-conductive surfaces are applied on the upper side and the lower side of the substrate.

39. The method as claimed in claim 38, wherein the structured electrically-conductive surfaces on the upper side and the lower side of the substrate electrically connected to one another by providing bores, the walls of which are provided with a metal layer by the electrolytic coating, in the substrate.

40. The method as claimed in claim 23, wherein the electrically nonconductive material, from which the support is made, is a resin-impregnated fabric or glass fiber-reinforced plastic which is pressed to form plates or rolls, a plastic sheet, a ceramic material, glass, silicon or a textile.

41. The method as claimed in claim 23 for producing conductor tracks on printed circuit boards, RFID antennas, transponder antennas or other antenna structures, chip card modules, flat cables, seat heaters, foil conductors, conductor tracks in solar cells or in LCD/plasma screens or for producing electrolytically coated products in any form.

42. The method as claimed in claim 23 for producing decorative or functional surfaces on products, which are used for example for shielding electromagnetic radiation, for thermal conduction or as packaging.

43. A device comprising an electrically nonconductive support with the electrically-conductive surfaces arranged thereon, in which the electrically-conductive surfaces are arranged in at least two planes and an insulating layer may be formed at the crossing points of the conductive structures of the at least two planes, wherein the electrically-conductive surfaces contain a base structure of electrically-conductive particles in a matrix material, which are coated with a metal layer, and the insulating layer consists of a printable electrically insulating material, wherein the structured and/or full area electrically-conductive surfaces have a layer thickness in the range from 0.05 to 25 μm.

44. The device as claimed in claim 43, produced by a method as claimed in claim 23.
